(19) United States
(12) Patent Application Publication
(10) Pub. No.: US 2015/0077115 A1
(43) Pub. Date: Mar. 19, 2015

(54) METHOD AND COMPUTER TO DETERMINE A B0 FIELD MAP WITH A MAGNETIC RESONANCE APPARATUS

(71) Applicant: Siemens Aktiengesellschaft, Muenchen (DE)

(72) Inventors: Hans-Peter Fautz, Forchheim (DE); Patrick Gross, Ismaning (DE); Rene Gumbrecht, Herzogenaurach (DE)

(73) Assignee: Siemens Aktiengesellschaft, Muenchen (DE)

(21) Appl. No.: 14/487,541

(22) Filed: Sep. 16, 2014

(30) Foreign Application Priority Data
Sep. 17, 2013 (DE) 102013218636.3

(51) Int. Cl. G01R 33/44; G01R 33/24; G01R 33/565

(52) U.S. Cl. CPC G01R 33/443; G01R 33/56563; G01R 33/243
USPC 324/318

(57) ABSTRACT

In a method to determine a B0 field map describing the local deviation of a nominal Larmor frequency of a magnetic resonance apparatus, wherein magnetic resonance data are acquired in measurements implemented at two different echo times whose difference forms a dephasing time after an excitation at at least two different dephasing times, and a phase change to be used to determine the B0 field map is determined from a difference of phases measured at different echo times, the phase changes of different dephasing times are evaluated to at least partially reduce an ambiguity due to a Nyquist phase wrapping, by using dephasing times that result as a quotient or, given the use of only two dephasing times, as a product, of a base time and a respective prime number from a group including at least two different prime numbers that are greater than one, and wherein the group is selected depending on a desired dynamic range of the B0 field map and/or a maximum tolerated measurement error for the measurements.

### BACKGROUND OF THE INVENTION

1. Field of the Invention

The invention concerns a method to determine a B0 field map describing the local deviation of a nominal Larmor frequency of a magnetic resonance apparatus, wherein magnetic resonance data are acquired at at least two different dephasing times after an excitation in measurements implemented at two different echo times whose difference forms a dephasing time, and a phase change to be used to determine the B0 field map is determined from a difference of phases measured at different echo times, wherein the phase changes of different dephasing times are evaluated to at least partially reduce an ambiguity due to a Nyquist phase wrapping. The invention also concerns a computer and a non-transitory, computer-readable data storage medium encoded with programming instructions to implement such a method.

2. Description of the Prior Art

Magnetic resonance imaging and its principles are widely known. A subject to be examined is introduced into a basic magnetic field with a relatively high field strength (known as the B0 field). In order to be able to acquire magnetic resonance data (for example in a slice of a subject), nuclear spins of this slice are excited and the decay of this excitation is considered as a signal, for example. Gradient fields can be generated by a gradient coil arrangement while radio-frequency excitation pulses (often designated as radio-frequency pulses) are emitted via a radio-frequency coil arrangement. By the entirety of the radio-frequency pulses (“excitation”), a radio-frequency field is generated that is typically designated as a B1 field, and the spins of nuclei excited to resonance are flipped by the gradients with spatial resolution by an amount known as a flip angle relative to the magnetic field lines of the basic magnetic field. The excited spins of the nuclei then radiate radio-frequency signals that can be acquired by suitable reception antennas (in particular the radio-frequency coil arrangement used for excitation) and processed further in order to reconstruct the magnetic resonance image data.

Conventional radio-frequency coil arrangements are operated in a mode known as a “homogeneous mode”—for example in a “CP mode” (circularly polarized mode)—wherein a single radio-frequency pulse with a defined, fixed phase and amplitudes is provided to all components of the transmission coil, for example to all transmission rods of a birdcage antenna. To increase the flexibility and to achieve new degrees of freedom to improve the imaging, it has been proposed to also enable operation in a mode as parallel transmission (pTX), in which multiple transmission channels of a radio-frequency coil arrangement are individually charged with individual pulses that can deviate from one another. This entirety of the individual pulses (which can be described by the parameters of phase and amplitude) is then defined overall in a control sequence that is described by a corresponding parameter set. Such a multichannel pulse (excitation) that is composed of individual pulses for the different transmission channels is often designated as a “pTX pulse” (for “parallel transmission”). In addition to the generation of spatially selective excitations, field inhomogeneities can also be compensated (for example within the scope of the “RF shimming”).

In order to determine control parameter sets of a control sequence, it is necessary to know the background (thus the B0 field) and the effects of the individual transmission channels in the imaging region (in particular the homogeneity volume).

To measure the basic magnetic field (B0 field)—designated as B0 mapping—magnetic resonance data are typically acquired at two different echo times, preferably by gradient echo imaging. The phase difference (phase change) of the magnetic resonance data acquired at different echo times—which phase difference can be determined via subtraction of the phases of two magnetic resonance images of the magnetic resonance data that are acquired at two different echo times—is proportional to a deviation of the local B0 field from the nominal basic magnetic field strength and to the dephasing time (thus the difference of the two echo times). The field deviation is specifically described by a deviation of the Larmor frequency from a nominal Larmor frequency of the magnetic resonance apparatus (a variable describing this deviation is most often designated in the following as a Larmor frequency value).

The phase generated by deviations in the homogeneity of the B0 field thus develops over time, wherein the effect of the Nyquist phase wrapping is to be considered. This is because the proportionality of the phase difference of magnetic resonance data acquired at different times to the deviation of the nominal Larmor frequency, and the difference of the echo times, is only valid as long as the phase difference limited to 2π corresponds to the actual phase evolution. However, the phases can be locally developed further by multiples of 2π depending on the dynamic range of the B0 distribution. This leads to ambiguities and errors in the calculation of the B0 maps. Incorrect associations in the phase evolution appear in non-physical spatial discontinuities (jumps) due to the 2π discontinuities in the phase difference images. This means that, if the deviation of the local Larmor frequency from the nominal Larmor frequency is large, an extremely fast development of the B0 phase also occurs so that, when the echo time (here the difference of the two echo times) is not short enough, the phase will be exceeded beyond 2π, such that the described ambiguity occurs.

The selection of extremely short dephasing times is often not possible due to the sequences that are used, wherein, given an extremely short echo time difference, smaller deviations from the nominal Larmor frequency can no longer be measured with sufficient precision.

A few approaches are known in the prior art to solve the ambiguity problem in the association of the measured phase change. It is thus possible to choose the dephasing time (thus the difference of the echo times) to be so short that at no point during it do the phases develop by more than 2π. However, since the dynamic range of the B0 field distribution is not known before the measurement, the dephasing time must be chosen to be so short that the sensitivity of the acquisition method is insufficient, and this procedure is consequently not used (as has already been presented).

Therefore, it has been proposed to detect and correct phase discontinuities in the B0 maps in a post-processing, under the assumption that the B0 field is spatially continuous. Algorithms that produce this effect are designated as phase unwrapping algorithms. However, the reliability of such algorithms is often in question. The primary difficulty is that the entire volume can consist of non-contiguous partial regions, such that individual partial regions of the B0 maps are separated by voxels that include only noise and are very low in signal. The phase in these voxels can thus not be determined, or can only be determined very unreliably.

It has also been proposed to iteratively acquire magnetic resonance data with increasing dephasing time, consequently increasing difference between the echo times. The shortest dephasing time is thereby chosen so that no spatial phase discontinuities occur. From the exposures with shorter dephasing times it is estimated whether a phase discontinuity will occur given longer dephasing time. If this applies, this is taken into account in the evaluation (reconstruction) of the magnetic resonance data with longer dephasing time. The phase ambiguity is therefore resolved, and long dephasing times are enabled for a high sensitivity.

An additional alternative procedure is to minimize the phase gradients between adjacent voxels in the B0 maps. Given this solution, the B0 maps do not necessarily need to be corrected for phase discontinuities. However, the risk exists that a calculated B0 shim is optimized for false B0 offsets in different spatial areas. Moreover, no frequency (shim of zeroth order) can be calculated from differential methods.

The acquisition of echoes at different dephasing times has turned out to be the most promising variant. Methods have also been proposed in which multiple echoes have been acquired during a measurement process (thus after an excitation), such that different dephasing times result even given one measurement.

The selection of the dephasing times is essential for a high-quality and reliable determination of the B0 field map. For this, from an article by Joseph Dagher et al., “A method for efficient and robust estimation of low noise, high dynamic range B0 maps”, Proc. Intl. Soc. Mag. Reson. Med. 20 (2012), Page 613, it is known to use an optimization approach to determine the dephasing times that is based on simulated cooling (simulated annealing). However, there is no guarantee of an actual optimal solution.

### SUMMARY OF THE INVENTION

An object of the invention is to provide a method to determine a qualitatively high-grade, more reliable B0 field map.

This object is achieved by a method of the aforementioned type but wherein, according to the invention, dephasing times are used that result as a quotient or—given the use of only two dephasing times—as a product of a base time and a respective prime number from a group including at least two different prime numbers that are greater than one, the group is selected depending on a desired, dynamic range region of the B0 field map and/or a maximum tolerated measurement error for the measurements.

The dephasing times are inventively selected based on an analytical approach, so that they are based on prime numbers. This allows an analytical solution of the problem of the selection of the dephasing times that delivers an optimal dynamic range and an optimal resolution that is determined by the base time. The derivation of these correlations should be briefly sketched in the following.

It is known that the phase change ΔΦ occurring during a dephasing time ΔTE is proportional to the B0 offset ΔB0 relative to the nominal Larmor frequency:

ΔB0=Δφ/(2πγΔTE) (1)

γ thereby designates the gyromagnetic ratio. However, if Nyquist phase wrapping (thus the 2π periodicity) is considered, an infinitely large number of solutions instead exists, namely

ΔB0=n·Δφ/(2πγΔTE) (2)

wherein n is a natural number. However, if measurements are implemented at different dephasing times ΔTEᵢ,

ΔB0=n₁·Δφ₁/(2πγΔTE₁)=n₂·Δφ₂/(2πγΔTE₂) (3)

must apply for the correct solution given two measurements, for example. The number of possible n is thus reduced, which increases dynamic range. The dynamic range can be controlled by a suitable selection of the dephasing times.

However, it should also be taken into account that a certain measurement precision or sensitivity is present so that the probability of determining a defined frequency or, respectively, a defined frequency offset is not a δ function, but rather has a certain breadth, for example is to be formed as a Gaussian distribution. However, this means that—even given different frequencies or frequency offsets, probability densities having their maximum, wherein the maximums or peaks repeat due to the Nyquist phase wrapping every 2π (see Equation (2))—the peaks nevertheless can overlap and can therefore lead to an incorrect assessment. This means that the selection of the echo times must also be such that peaks of the probability densities are sufficiently spaced for different echo times, in particular if the risk exists that an effective probability determined for an incorrect peak is greater than that determined for the correct peak, which can occur for defined applications. The spacing of the peaks should thus also be taken into account.

It is consequently advantageous if how large the maximum errors that can still be tolerated should be is also involved in the selection of the dephasing times, which results from the properties of the peaks in the probability function and is detectable via measurements. For example, the maximum tolerable measurement errors can be determined so that it defines a region in which the measurement values are present in at least 95%—preferably 99% or more than 99%—of all measurements. In this way, the noise is also involved in the selection of the dephasing times.

It is noted that additional boundary conditions naturally also exist in the selection of the dephasing times (and consequently the echo times) which additional boundary conditions must, however, be considered in principle, for example the fundamental feasibility of the echo times with the magnetic resonance sequence (preferably a gradient echo sequence) that is used, which will be discussed in detail in the following.

The echo spacings or peak spacings that are established by the dephasing times should thus be selected in the method according to the invention, such that the dynamic range is (markedly) increased in comparison to a single dephasing time, and at the same time the sensitivity of the measurement to the phase noise is kept as low as possible. In other words, this means that the combined periodicity of all probability density functions should be greater than the periodicity of the smallest dephasing time, as a formula:

$$\frac{2 π}{min ( Δ {TE}_{i} )} < {min}_{{n}_{i}} ( \frac{2 π {n}_{1}}{Δ {TE}_{1}} = \frac{2 π {n}_{2}}{Δ {TE}_{2}} = … = \frac{2 π {n}_{I}}{Δ {TE}_{I}} ) . \qquad ( 4 )$$

Δφ=0 is thereby assumed without limitation. I is the total number of dephasing times. In order to solve the minimization problem provided by Equation (4), two different approaches are conceivable, namely

ΔTEᵢ:=α·pᵢ (5a)

and

ΔTEᵢ:=α/pᵢ (5b),

wherein α is the base time, pᵢ are the prime numbers of the group with i=1 . . . I members. The solutions of the respective minimization problem are then

$$\begin{matrix}{n}_{i} = {\prod }_{l} {p}_{l} \\ or , respectively , & ( 6 a ) \\ {n}_{i} = {p}_{i} & ( 6 b )\end{matrix}$$

if all pᵢ have no common prime factors. If pᵢ have common prime factors, a smaller nᵢ can always be found that satisfies Equation (7).

The first solution—Equations (5a) and (6a)—of the minimization problem always yields a result of 2π. This solution is only usable for two dephasing times (echo spacings). If a third dephasing time is added, the dynamic range no longer increases. The second solution—equations (5b) and (6b)—increases the dynamic range with every additional dephasing time, and therefore offers a much greater flexibility. The use of a quotient according to the invention is therefore also preferred. However, it is noted that both solutions provide the same results for two dephasing times.

For a more precise depiction, the second solution is presented in detail. Given the approach according to equation (5b), the dynamic range results as

$${Δω}_{max} = \frac{2 π}{α} {\prod }_{i} {p}_{i} \qquad ( 8 b )$$

The expansion of the dynamic range comes at the cost of an increased sensitivity to noise, as already presented. In order to avoid the noise in the measured magnetic resonance data leading to a false determination of a B0 map, the noise sensitivity of a set of dephasing times should be quantified. As shown above, the noise sensitivity directly coincides with the spacing of two maxima of the probability density functions of different dephasing times:

$${min}_{i , j} ( \frac{2 π {n}_{i}}{Δ {TE}_{i}} - \frac{2 π {n}_{j}}{Δ {TE}_{j}} ) = {min}_{i , j} ( {n}_{i} {p}_{i} - {n}_{j} {p}_{j} ) . \qquad ( 9 )$$

One obvious solution to this problem is zero, but this lies directly outside of the dynamic range and so is not relevant. The next possible solution is 1. It can be shown numerically that for

nᵢpᵢ−nⱼpⱼ=1 (10)

a solution always exists for (small) prime numbers. The minimum distance between two possible frequencies can then be calculated as

$${Δω}_{min} = \frac{2 π}{α} , \qquad ( 11 b )$$

from which it follows for the associated phase changes (which can be resolved):

$${Δφ}_{min} = \frac{2 π}{{max}_{i} ( {p}_{i} )} . \qquad ( 12 b )$$

Equation (12b) describes the maximum tolerable measurement errors for the phase changes; in other words, the use of the dephasing times selected with prime numbers thus “immunizes” the B0 field map determination against noise in the range described by Equation (12b), but outside of this range the B0 field map can deviate markedly from the real values at points, in particular more markedly than the noise level of the acquired magnetic resonance data would indicate. It is consequently advantageous to choose the dephasing times so that a measurement error lying outside of the range defined by Equation (12b) is at least extremely improbable.

Equations equivalent to Equations (8b), (11b) and (12b) can be determined for the approach based on first solution as:

$$\begin{matrix}{Δω}_{max} = \frac{2 π}{α} & ( 8 a ) \\ {Δω}_{min} = \frac{2 π}{α {\prod }_{i} {p}_{i}} & ( 11 a ) \\ {Δφ}_{min} = \frac{2 π}{{min}_{i} ( {p}_{i} )} . & ( 12 a )\end{matrix}$$

In embodiments for the approach based on first solution, given use of a product, the base time and the prime numbers of the group are chosen so that at least the desired dynamic range results as 2π divided by the base time, and at least the maximum tolerated measurement error for the phase results for the quotient of 2π and the smallest prime number of the group. For the preferred approach that is based second solution (which offers more flexibility), given use of a quotient, the base time and the prime numbers of the group are chosen so that at least the desired dynamic range results as the product of two, pi and all prime numbers of the group divided by the base time, and/or at least the maximum tolerated measurement error for the phase results for the quotient of two times pi and the largest prime number of the group.

Unambiguous boundary conditions are present that yield suitable dephasing times for the corresponding imaging task, which is defined by the (minimal) desired dynamic range and the maximum tolerable measurement errors. In the preferred case of the calculation of a quotient (Equations (5b) and the following), a base time can already result from the maximum tolerable error (which error can, however, also be considered retroactively because the essential requirement is the desired dynamic range), at which base time suitable prime numbers (and thus the group) can then easily be established. In tests, it has been shown that prime numbers that are greater than 13 are rarely actually used since sufficiently large dynamic ranges are already achieved with lower prime numbers, at least in the range of the dephasing times or echo times that are accessible anyway via gradient echo sequences. Consequently, the prime numbers of the group are chosen to be less than 17, which can be viewed as an additional boundary condition. In particular, this markedly limits the number of available prime numbers that are greater than one, such that a manageable number of possibilities is created from which suitable groups can easily be formed that satisfy the boundary conditions.

Generally speaking, the prime numbers of the group and the base time are determined in an optimization method for a given dynamic range and given maximum tolerated measurement error. If the prime number space (and also the space of possible base times corresponding to the selected magnetic resonance sequence) is limited, a suitable solution for different applications or, respectively, concrete magnetic resonance devices and concrete magnetic resonance sequences can also easily be found automatically.

It should be noted that the selection of suitable dephasing times naturally does not need to take place “online” immediately before a specific measurement of the B0 field map; rather (because magnetic resonance devices and their properties upon manufacture are known, which also applies to the typical applications), suitable dephasing times can already be established so that suitable dephasing times can be “co-delivered” in the development of a magnetic resonance apparatus. However, a dynamic determination is also possible, for example if new applications are realized in a magnetic resonance apparatus or if variations in the hardware result (for example via the use of new coils).

However, in general the magnetic resonance data are acquired with a gradient echo sequence, as already been noted.

As also noted, other boundary conditions can naturally enter into the selection of the base time and the prime numbers of the group; in particular, it is preferred for the dephasing times to be determined so that all of them can be measured in different echoes after an excitation. Ultimately, the scan time is therefore added as an additional optimization goal. To minimize dead times, it can also be provided that the dephasing times are chosen so that echoes distributed as equally as possible are measured.

In another variant, each dephasing time is measured in its own measurement. This is appropriate, for example, if the B0 mapping should be combined with a B1 mapping and a dephasing time is also covered for each B1 acquisition process, thus if a second echo is measured. In such an embodiment, boundary conditions that relate to the repetition time and the even distribution of the echoes would be less significant.

B0 field maps can be measured using a standard 3D multi-echo gradient echo sequence with isotropic resolution, for example. The dephasing times can be chosen in order to achieve a compromise between low noise sensitivity (via specification of the maximum tolerable measurement error), scan time, acquisition bandwidth and dynamic range. The minimization of the dead time that is described above can also take place. For example, the dephasing times can thus be chosen so that they are measured in a repetition time TR of approximately 10 ms with a minimized acquisition bandwidth, a maximized dynamic range and a maximum allowed phase error of 30°. For this purpose, the following algorithm can be used:

a) find the greatest possible prime number pₘₐₓ that satisfies Equation (12b) (or Equation (12a)) for a predetermined maximum tolerable measurement error of the phase change,

b) select three prime numbers from the interval [2 . . . pₘₐₓ] that allow equally spaced echoes to measure the dephasing times,

c) find the largest base time a according to Equation (8b) such that all echoes can be measured in the desired repetition time.

For example, if a maximum tolerable measurement error for the phase change is established as 30°, for instance, and a dynamic range of greater than 10 KHz is desired, 3.06 ms, 5.68 ms and 7.95 ms can result as resulting dephasing times which can be measured in echo times of 1.4 ms, 4.46 ms, 7.08 ms and 9.35 ms, wherein a group of prime numbers p, of 5, 7 and 13 and a base time a of 39.75 ms have been used. The maximum tolerable measurement error of approximately 30° is maintained, and a dynamic range of 11.5 KHz results. The resulting repetition time is 11 ms and the acquisition bandwidth is 530 Hz/px given a monopolar readout process. In this example scenario, the limiting factors are the scan time, the noise sensitivity and the acquisition bandwidth. For example, the complete acquisition time can amount to 19 s. Such an imaging protocol can be used for phantom scans and under corresponding selection of the field of view for in vivo scans.

In addition to the method, the invention also concerns a non-transitory, computer-readable data storage medium encoded with programming instructions designed for implementation of the method according to the invention when executed in a computer. For example, the storage medium can be a CD-ROM. All statements with regard to the method according to the invention apply analogously to the storage medium according to the invention. The same advantages can consequently be achieved. In specific exemplary embodiments, the computer can be a component of a magnetic resonance device.

### BRIEF DESCRIPTION OF THE DRAWINGS

FIG. 1 shows the probability density functions for different dephasing times.

FIG. 2 is a flowchart of an exemplary embodiment of the method according to the invention.

FIG. 3 schematically illustrates a computer according to the invention.

### DESCRIPTION OF THE PREFERRED EMBODIMENTS

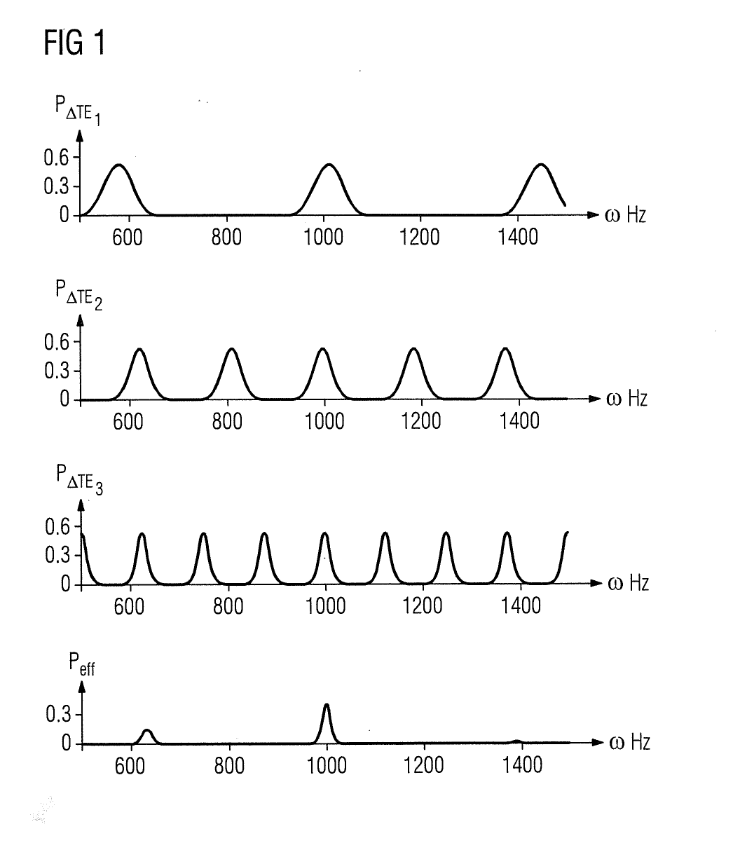

The present invention concerns the selection of suitable dephasing times given a measurement of B0 field maps using multiple different dephasing times. Ideally, an increased dynamic range should thereby be provided without losses occurring with regard to scan time and precision if it is compared with a highly precise measurement of a B0 field map with large echo spacing. Therefore, additional echoes are to be specifically selected and analytically derived echo times are measured, wherein the remaining B0 field map is reconstructed with a probability-based access. This, and the bases of the considerations, are explained in detail using FIG. 1.

In this, probability density functions P_{ΔTEi} are shown that reflect the probability that a defined frequency is the resonance frequency (Larmor frequency) of the corresponding voxel. The probability density functions clearly have a defined periodicity that is based on the Nyquist phase wrapping. The function P_{eff} shown below in FIG. 1 is the result of a multiplication of the three probability density functions P_{ΔTEi}. The greatest probability clearly results at approximately 1000 Hz, wherein yet another (markedly smaller) peak also occurs at approximately 600 Hz, triggered by the breadth through the noise in the measurement of phase changes. If these peaks are too high, an ambiguity can occur with regard to the actual Larmor frequency (or, respectively, deviation from the nominal Larmor frequency) in the voxel, in spite of which the dynamic range would be markedly larger if S-peaks are considered. Therefore, in the method according to the invention, not only boundary conditions related to the dynamic range and the magnetic resonance frequency that is used but also a maximum tolerable measurement error for the phase change (which ultimately describes the breadth of the periodically repeating peaks) are taken into account as boundary conditions for the determination of the dephasing times.

To reconstruct the B0 field maps, the single significant peak (in particular Gaussian peak) is then ultimately found within an expected range or the dynamic range. The core of the present invention is to specify how dephasing times can be selected in order to ensure this unambiguity in the desired dynamic range. It is noted, however, that the probabilistic approach described herein does not need to be used for ultimate determination of the B0 field maps; other possibilities are also conceivable to determine the correct deviations from the nominal Larmor frequency of the magnetic resonance device from the measured phase changes in the dynamic range.

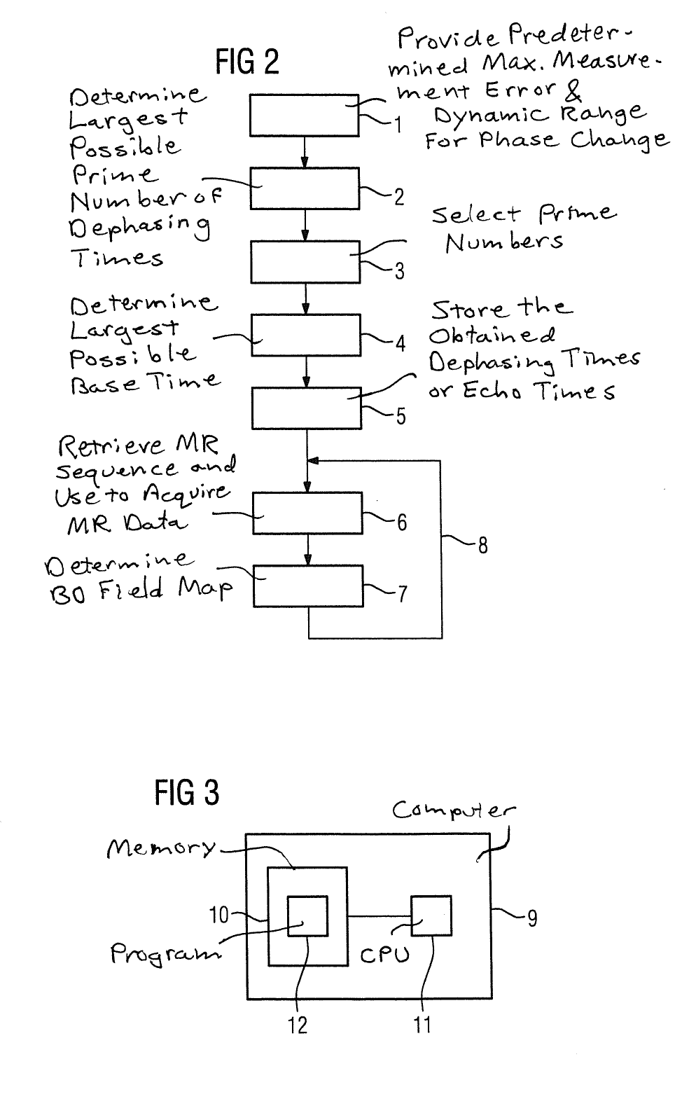

FIG. 2 shows a flowchart of an exemplary embodiment of the method according to the invention. A maximum tolerated measurement error for the phase change and a desired dynamic range that should be minimally provided are initially predetermined in step 1. In addition, it is defined which magnetic resonance sequence should be used to acquire the magnetic resonance data, presently a standard 3D multiecho gradient echo sequence.

Properties of the magnetic resonance apparatus to be used can also be predetermined. These specifications ultimately form boundary conditions for the following selection or determination of dephasing times, which automatically takes place within the scope of an optimization method in the exemplary embodiment shown here.

In step 2, a largest possible prime number pₘₐₓ is determined using Equation (12b), wherein the maximum tolerable error for the phase change is applied.

In the present exemplary embodiment, the number of dephasing times is established as three. Naturally, these can also be of open design, or a different number can be established. In step 3, in the exemplary embodiment three prime numbers are then chosen from the interval [2, . . . , pₘₐₓ] that are suitable to define dephasing times according to Equation (5b) that allow an optimally uniform distribution of echoes to be measured.

In step 4, the largest possible base time a is then determined according to Equation (8b), such that all echoes that are required to realize the dephasing times can be realized within a desired repetition time TR.

An example of a desired dynamic range that is greater than 10 KHz and a maximum tolerable measurement error of approximately 30° has already been explained above and uses echo times to acquire magnetic resonance data at 1.5 ms, 4.46 ms, 7.08 ms and 9.35 ms in order to realize dephasing times that are based on prime numbers 5, 7 and 13, as well as a base time of 39.75 ms. A dynamic range of 11.5 KHz therefore results according to Equation (8b). The repetition time amounts to 11 ms, and the acquisition bandwidth (which can also be optimized) amounts to 530 Hz/px given monopolar readout.

In step 5, the obtained dephasing times, or the echo times resulting therefrom (preferably the entire magnetic resonance sequence used to measure the B0 field map), are stored in a database.

If B0 field maps should then be measured later with the magnetic resonance apparatus, in step 6 the magnetic resonance sequence is retrieved from the database and the measurement of the magnetic resonance data takes place. Using the probabilistic approach discussed above, the desired B0 field map is determined in step 7, making use of the fact that effects of the Nyquist phase wrapping do not occur in the dynamic range. If a measurement of a B0 field map should take place again for the same application at a later point in time, the sequence data describing the magnetic resonance sequence can be retrieved from the database again (see arrow 8).

It is noted that embodiments of the method according to the invention are also possible wherein the dephasing times and associated echo times are determined “online” before a measurement, in particular when boundary conditions can dynamically change.

FIG. 3 shows a strongly simplified block diagram of a computer 9 according to the invention, that has a memory 10 and at least one CPU 11. A computer program 12 that realizes the method according to the invention if it is executed by the CPU 11 of the computer 9 is stored in the memory 10. The memory 10 can be a volatile or non-volatile memory so that the computer program 12 can be stored on a non-transient medium, for example a CD-ROM. The computer 9 can be part of a magnetic resonance apparatus, and in particular be designed as a control device of the magnetic resonance apparatus, such that it can also be designed to control the components of the magnetic resonance apparatus to acquire the magnetic resonance data and to determine the B0 field maps, in addition to the determination of the dephasing times (and consequently the magnetic resonance sequence).

Although modifications and changes may be suggested by those skilled in the art, it is the intention of the inventors to embody within the patent warranted hereon all changes and modifications as reasonably and properly come within the scope of their contribution to the art.

We claim as our invention:

1. A method to determine a B0 field map describing a local deviation from a nominal Larmor frequency in a magnetic resonance apparatus comprising:
providing magnetic resonance data to a computerized processor, said magnetic resonance data being acquired in measurements implemented at two different echo times in a data acquisition sequence, said two different echo times occurring at respectively different dephasing times following an excitation of nuclear spins;
in said processor, determining a B0 field map from a phase change determined from a different said phases measured at said different echo times;
in said processor, evaluating the respective phase changes of different dephasing times to at least partially reduce an ambiguity due to Nyquist phase wrapping by forming a quotient, when more than two dephasing times are present, or forming a product, when only two dephasing times are present, of a base time and a prime number selected from a group comprising at least two different prime numbers that are greater than one;
selecting said prime numbers in said group dependent on at least one of a desired dynamic range of said B0 field map and a maximum tolerated measurement error for said measurements; and
making the determined B0 field map available in electronic form at an output of said processor.

2. A method as claimed in claim 1 wherein only two dephasing times are present, and selecting said base time and said prime numbers in said group, for said product, to cause said desired dynamic range to be 2π divided by said base time, and to cause said maximum tolerated measurement error for said phase to be a quotient of 2π and the smallest prime number in said group.

3. A method as claimed in claim 1 wherein more than two dephasing times are present, and selecting said base time and said prime numbers in said group, for said quotient, to cause a desired dynamic range to be the product of 2π and all prime numbers of said group divided by said base time, and/or said maximum tolerated measurement error for said phase to be the quotient of 2π and the largest prime number in said group.

4. A method as claimed in claim 1 comprising selecting the prime numbers in said group to all be smaller than 17.

5. A method as claimed in claim 1 comprising determining said prime numbers in said group and said base time in said processor by executing an optimization algorithm for a predetermined dynamic range and a predetermined maximum tolerated measurement error.

6. A method as claimed in claim 1 comprising providing said processor with magnetic resonance data acquired with a gradient echo sequence.

7. A method as claimed in claim 1 comprising providing said computerized processor with magnetic resonance data having dephasing times all measured at different echos after said excitation.

8. A device to determine a B0 field map describing a local deviation from a nominal Larmor frequency in a magnetic resonance apparatus comprising:
a computerized processor provided with magnetic resonance data, said magnetic resonance data being acquired in measurements implemented at two different echo times in a data acquisition sequence, said two different echo times occurring at respectively different dephasing times following an excitation of nuclear spins;
said processor being configured to determine a B0 field map from a phase change determined from a different said phases measured at said different echo times;
said processor being configured to evaluate the respective phase changes of different dephasing times to at least partially reduce an ambiguity due to Nyquist phase wrapping by forming a quotient, when more than two dephasing times are present, or forming a product, when only two dephasing times are present, of a base time and a prime number selected from a group comprising at least two different prime numbers that are greater than one;
said prime numbers in said group being selected dependent on at least one of a desired dynamic range of said B0 field map and a maximum tolerated measurement error for said measurements; and
said processor being configured to make the determined B0 field map available in electronic form at an output of said processor.

9. A non-transitory, computer-readable data storage medium encoded with programming instructions, said storage medium being loaded into a computer and said programming instructions causing said computer to:
receive magnetic resonance data, said magnetic resonance data being acquired in measurements implemented at two different echo times in a data acquisition sequence, said two different echo times occurring at respectively different dephasing times following an excitation of nuclear spins;
determine a B0 field map from a phase change determined from a different said phases measured at said different echo times;
evaluate the respective phase changes of different dephasing times to at least partially reduce an ambiguity due to Nyquist phase wrapping by forming a quotient, when more than two dephasing times are present, or forming a product, when only two dephasing times are present, of a base time and a prime number selected from a group comprising at least two different prime numbers that are greater than one;
select said prime numbers in said group dependent on at least one of a desired dynamic range of said B0 field map and a maximum tolerated measurement error for said measurements; and
make the determined B0 field map available in electronic form at an output of said processor.
